(19) United States
(12) Patent Application Publication
(10) Pub. No.: US 2024/0106415 A1
(43) Pub. Date: Mar. 28, 2024

(54) SURFACE ACCOUSTIC WAVE FILTER WITH IMPROVED ATTENUATION

(71) Applicant: WISOL CO., LTD., Osan-si (KR)

(72) Inventors: Hyung Gon KIM, Osan-si (KR); Tae Hyeong KWON, Osan-si (KR); Jae Seung CHOI, Osan-si (KR)

(21) Appl. No.: 18/471,465

(22) Filed: Sep. 21, 2023

(30) Foreign Application Priority Data
Sep. 23, 2022 (KR) 10-2022-0120555

(51) Int. Cl. H03H 9/64; H03H 9/02; H03H 9/145; H03H 9/25

(52) U.S. Cl. CPC H03H 9/6489; H03H 9/02992; H03H 9/14541; H03H 9/25

(57) ABSTRACT

Provided is a surface acoustic wave filter with improved attenuation characteristics. The surface acoustic wave filter includes: a plurality of series resonators which are connected between an input terminal and an output terminal; and at least one parallel resonator which connects between a ground terminal and two adjacent series resonators among the plurality of series resonators, wherein at least one of the plurality of series resonators includes: first and second bus bars, which extend parallel to each other in a first direction within first to third areas sequentially arranged on a substrate; a plurality of first interdigital (IDT) transducer electrodes which extend in a second direction perpendicular to the first direction from the first bus bar; and a plurality of second IDT electrodes which extend in the second direction from the second bus bar and are alternately arranged with the plurality of first IDT electrodes, wherein the plurality of first IDT electrodes and the plurality of second IDT electrodes are alternately arranged with a reference period in the second area, are alternately arranged in the first area with a period which gets smaller than a reference period in the direction of one end of the first bus bar, and are alternately arranged in the third area with a period which gets smaller than a reference period in the direction of the other end of the first bus bar.

### BACKGROUND OF THE INVENTION

### Field of the Invention

The present invention relates to a surface acoustic wave filter with improved attenuation characteristics, and more specifically, to a surface acoustic wave filter which can improve the right-side attenuation characteristics by adjusting the period of interdigital transducer (IDT) electrodes included in a resonator of the surface acoustic wave filter.

### BACKGROUND ART

A surface acoustic wave (SAW) refers to a wave propagating along the surface of an elastic solid. Such a surface acoustic wave concentrates and propagates energy close to the surface, and corresponds to a mechanical wave. A surface acoustic wave element is an electro-mechanical device which utilize the interaction between the surface acoustic waves and semiconductor conductive electrons, and uses the surface acoustic waves transferred onto the surface of piezoelectric crystals.

Such a surface acoustic wave element can have a wide range of industrial applications including sensors, oscillators, and filters, can be miniaturized and made lightweight, and can have various benefits such as durability, stability, sensitivity, affordability, and real-time capabilities.

Meanwhile, the surface acoustic wave element can form a pectinate interdigital transducer (IDT) electrode on a piezoelectric substrate, and can generate corrugated waves when a signal is input. In this instance, the speed of the waves formed on the surface of the substrate can vary depending on the period (Pitch) between electrodes. Therefore, a filter having the surface acoustic wave element can adjust characteristics of the filter by changing factors, such as the period of the IDT electrode, a duty factor which is a ratio of the electrode in the period, and the width of the electrode.

### PATENT LITERATURE

### Patent Documents

Patent Document 1: Korean Patent Publication No. 10-2012-0114729 (Oct. 17, 2012)

### SUMMARY OF THE INVENTION

Accordingly, the present invention has been made to solve the above-mentioned problems occurring in the prior arts, and it is an objective of the present invention to provide a surface acoustic wave filter with improved attenuation characteristics by adjusting the period of interdigital transducer (IDT) electrodes included in a resonator of the surface acoustic wave filter.

It is another objective of the present invention to provide a surface acoustic wave filter with improved attenuation characteristics by using a capacitor connected to the resonator of the surface acoustic wave filter.

The objectives of the present disclosure are not limited to those mentioned above, and other objectives not mentioned herein will be clearly understood by those skilled in the art from the following description.

To accomplish the above object, according to the present invention, there is provided a surface acoustic wave filter with improved attenuation characteristics including: a plurality of series resonators which are connected between an input terminal and an output terminal; and at least one parallel resonator which connects between a ground terminal and two adjacent series resonators among the plurality of series resonators, wherein at least one of the plurality of series resonators includes: first and second bus bars, which extend parallel to each other in a first direction within first to third areas sequentially arranged on a substrate; a plurality of first interdigital (IDT) transducer electrodes which extend in a second direction perpendicular to the first direction from the first bus bar; and a plurality of second IDT electrodes which extend in the second direction from the second bus bar and are alternately arranged with the plurality of first IDT electrodes, wherein the plurality of first IDT electrodes and the plurality of second IDT electrodes are alternately arranged with a reference period in the second area, are alternately arranged in the first area with a period which gets smaller than a reference period in the direction of one end of the first bus bar, and are alternately arranged in the third area with a period which gets smaller than a reference period in the direction of the other end of the first bus bar.

In several embodiments of the present invention, the period at which the plurality of first IDT electrodes and the plurality of second IDT electrodes are arranged in the first and third areas decreases towards the one end or the other end of the first bus bar within a range of 88% to 97% of the reference period.

In several embodiments of the present invention, at least one of the plurality of series resonators has two or more resonant frequencies and anti-resonant frequencies.

In several embodiments of the present invention, the surface acoustic wave filter further includes a first capacitor which is connected in parallel with a first series resonator among the plurality of series resonators.

In several embodiments of the present invention, the first capacitor has a metal-insulator-metal (MIM) structure.

In several embodiments of the present invention, the first series resonator has the highest resonant frequency among the plurality of series resonators.

In several embodiments of the present invention, the first capacitor decreases the electromechanical coupling coefficient (K²) of the first series resonator.

In several embodiments of the present invention, the surface acoustic wave filter further includes a second capacitor which is connected in parallel with a second series resonator among the plurality of series resonators.

In several embodiments of the present invention, the second series resonator has the second highest resonant frequency among the plurality of series resonators, after the resonance frequency of the first series resonator.

In several embodiments of the present invention, the second capacitor has an IDT capacitor structure or an MIM structure.

In several embodiments of the present invention, at least one of the plurality of series resonators includes: a first reflector formed on the substrate to face the one end of the first bus bar; and a second reflector formed on the substrate to face the other end of the first bus bar.

In another aspect of the present invention, there is provided a surface acoustic wave filter including: a plurality of series resonators which are connected between an input terminal and an output terminal; a first capacitor which is connected in parallel with a first series resonator among the plurality of series resonators; and at least one parallel resonator which connects between a ground terminal and two adjacent series resonators among the plurality of series resonators, wherein at least one of the plurality of series resonators includes: first and second bus bars, which extend parallel to each other in a first direction within first to third areas sequentially arranged on a substrate; a plurality of first interdigital (IDT) transducer electrodes which extend in a second direction perpendicular to the first direction from the first bus bar; and a plurality of second IDT electrodes which extend in the second direction from the second bus bar and are alternately arranged with the plurality of first IDT electrodes, wherein the plurality of first IDT electrodes and the plurality of second IDT electrodes are alternately arranged with a reference period in the second area, and are alternately arranged in the first area and the third area with a period different from the reference period, and wherein the first series resonator has the highest resonant frequency among the plurality of series resonators.

In several embodiments of the present invention, the plurality of first IDT electrodes and the plurality of second IDT electrodes are alternately arranged in the first area with a period which gets smaller than a reference period in the direction of one end of the first bus bar, and are alternately arranged in the third area with a period which gets smaller than a reference period in the direction of the other end of the first bus bar.

Detailed matters of other embodiments are included in the detailed description and drawings.

The surface acoustic wave filter according to an embodiment of the present invention includes interdigital transducer (IDT) electrodes which are included in series resonators and have an arrangement period that is gradually decreased toward one side or the other side of the series resonator, thereby causing additional resonance/anti-resonance phenomena induced by the electrodes. By the additionally generated resonance/anti-resonance, the attenuation characteristics on the right side of a transmission band can be improved.

Moreover, the surface acoustic wave filter with improved attenuation characteristics according to an embodiment of the present invention includes a capacitor which is connected in parallel with at least one of the series resonators to reduce the electromechanical coupling coefficient (K²) and anti-resonance frequency of the relevant series resonator, thereby improving the right-side attenuation characteristics on the right side.

Specifically, the series resonator to which the capacitor is connected can most significantly affect the right-side attenuation characteristics of the surface acoustic wave filter since having the highest resonance frequency, thereby maximizing the characteristic improvement effect due to the capacitor connection.

The advantages of the present disclosure are not limited to the above-mentioned advantages, and other advantages, which are not specifically mentioned herein, will be clearly understood by those skilled in the art from the following description.

### BRIEF DESCRIPTION OF THE DRAWINGS

FIG. 1 is a circuit diagram of a surface acoustic wave filter with improved attenuation characteristics according to several embodiments of the present invention.

FIG. 2 is a view illustrating a structure of a series resonator included in the surface acoustic wave filter of FIG. 1.

FIG. 3 is a graph for depicting a period of the series resonator of FIG. 2.

FIG. 4 is a graph for depicting improved attenuation characteristic effect obtainable when the surface acoustic wave filter of the present invention has the structure of the series resonator of FIG. 2.

FIG. 5 is a graph showing an enlargement of a portion of FIG. 4.

FIGS. 6 and 7 are graphs for depicting improved attenuation characteristic effect obtainable by a capacitor included in the surface acoustic wave filter of the present invention.

FIG. 8 is a circuit diagram of a surface acoustic wave filter with improved attenuation characteristics according to another embodiment of the present invention.

### DETAILED DESCRIPTION OF THE PREFERRED EMBODIMENT

Advantages and features of the present disclosure and methods accomplishing the advantages and features will become apparent from the following detailed description of exemplary embodiments with reference to the accompanying drawings. However, the present invention is not limited to exemplary embodiment disclosed herein but will be implemented in various forms. The exemplary embodiments are provided so that the present invention is completely disclosed, and a person of ordinary skilled in the art can fully understand the scope of the present invention. Therefore, the present invention will be defined only by the scope of the appended claims. The sizes of components and the relative sizes illustrated in the drawings may be exaggerated for clarity. In addition, like reference numerals designate like elements throughout the specification, and the term “and/or” is understood to include each of mentioned items and one or more combinations of the items.

It will be understood that, when an element or a layer is referred to as being on another element, the element or layer can be directly on the other element or layer, or intervening elements may be present. On the other hand, when an element is referred to as being “directly on” or “right on”, it means that there is no intervening element or layer.

Terms, such as “below,” “beneath,” “lower,” “above,” “upper,” and the like, which have spatially relative concepts, may be used to facilitate correlation between one component and other components, as illustrated in the drawings. Such spatially relative terms should be understood as terms including different directions of components during use or operation, in addition to the direction illustrated in the drawings. For example, if the components illustrated in the drawings are turned upside down, the components described as “below” or “beneath” may be arranged “above” of other components. Thus, the exemplary term “under” may include all of the directions, “below” and “above”. The components may be oriented in other directions, so that the spatially relative terms can be interpreted according to the orientation.

Terms used in the specification are provided for description of the exemplary embodiments, and the present invention is not limited thereto. In the specification, singulars in sentences include plural unless otherwise noted. It will be understood in the specification that the terms “comprises” and “comprising”, when used herein, specify the presence of constituent elements, but do not preclude the presence or addition of other constituent elements.

It will be understood that terms, such as “first” or “second” may be used in the specification to describe various components but are not restricted to the above terms. The terms may be used to discriminate one component from another component. Therefore, of course, the first component may be named as the second component within the scope of the present disclosure. Unless otherwise defined, all terms (including technical and scientific terms) used herein have the same meaning as commonly understood by those skilled in the technical field to which the present disclosure pertains. It will be further understood that terms, such as those defined in commonly used dictionaries, should not be interpreted in an idealized or overly formal sense unless expressly so defined herein.

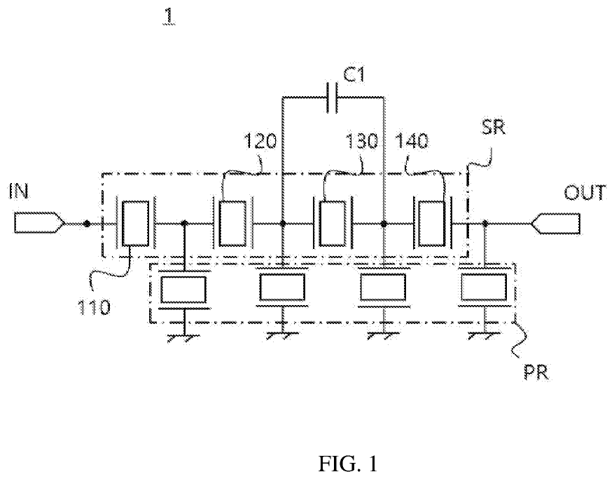

FIG. 1 is a circuit diagram of a surface acoustic wave filter with improved attenuation characteristics according to several embodiments of the present invention.

Referring to FIG. 1, a surface acoustic wave filter 1 according to several embodiments of the present invention can include: a plurality of series resonators (SR); parallel resonators (PR) connecting between adjacent series resonators and a ground terminal; and capacitors (C1) which are connected in parallel to at least one of the plurality of series resonators.

One or more series resonators (SR) can be connected between an input terminal (IN) and an output terminal (OUT). FIG. 1 illustrates four series resonators 110, 120, 130, and 140 which are connected between the input terminal (IN) and the output terminal (OUT), but the invention is not limited thereto.

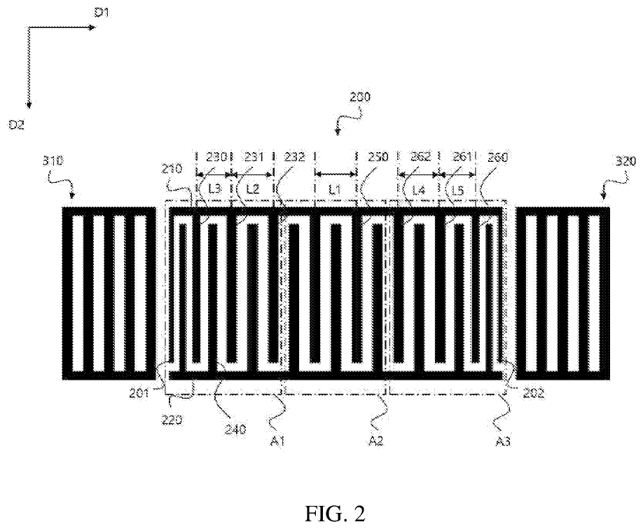

At least one of the multiple series resonators (SR) can have the structure illustrated in FIG. 2. Further details will be described later.

At least one of the multiple series resonators (SR) can have two or more resonance frequencies and two or more anti-resonance frequencies, respectively. In this case, the resonance frequencies and the anti-resonance frequencies of the relevant series resonator may be higher than the center frequency.

The parallel resonator (PR) can connect between the two adjacent series resonators (for example, 110 and 120) of the plurality of series resonators and a ground terminal. FIG. 1 illustrates all of the parallel resonators (PR) are connected between the adjacent series resonators, but the invention is not limited thereto, and there might be series resonators to which no parallel resonator is connected.

A first capacitor (C1) can be connected in parallel with at least one of the plurality of series resonators (SR). The first capacitor (C1) can have a metal-insulator-metal (MIM) structure that a dielectric material, such as Ta₂O₅, is interposed between two metal electrodes.

The first capacitor (C1) can be connected in parallel to the series resonator, which most significantly affects the right-side attenuation characteristics of the surface acoustic wave filter 1, among the plurality of series resonators (SR). Therefore, the first capacitor (C1) can be connected to the series resonator, of which the resonance frequency is the highest, among the plurality of series resonators (SR). FIG. 1 illustrates that the series resonator 130 is set to have the highest resonance frequency, and the first capacitor (C1) is connected to the series resonator 130.

The first capacitor (C1) can reduce the electromechanical coupling coefficient (K2) of the parallelly connected series resonator 130. As the electromechanical coupling coefficient (K2) decreases, the difference between the resonance and anti-resonance frequencies can reduce, and attenuation and skirt characteristics of the surface acoustic wave filter 1 can be improved.

In an embodiment of the present invention, the parallel resonator (PR) included in the surface acoustic wave filter can have an anti-resonance frequency which is lower than the resonance frequency of the series resonator 110 to which the parallel resonator (PR) is connected. Furthermore, the width of an interdigital transducer (IDT) electrode in the parallel resonator (PR) can be greater than that of the IDT electrode of the series resonator 110 to which the parallel resonator (PR) is connected.

In accordance with frequency characteristics obtainable by using the surface acoustic wave filter according to an embodiment of the present invention, one or more resonators (PR) can be connected between at least one series resonator (SR) and the ground terminal. FIG. 1 illustrates that four resonators (PR) are connected between the resonators 110 and 120, 120 and 130, and 130 and 140 and the output terminal (OUT), but the invention is not limited thereto. Alternatively, one or more resonators can be connected between two series resonators and the ground terminal.

Referring to FIG. 2, a structure of at least one series resonator (SR) included in the surface acoustic wave filter according to an embodiment of the present invention will be described in more detail.

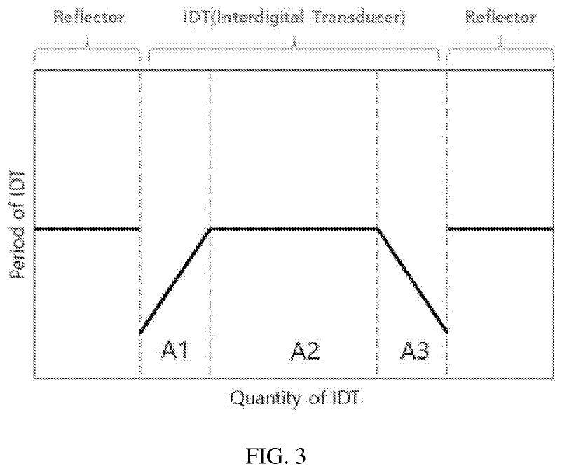

FIG. 2 is a view illustrating a structure of a series resonator included in the surface acoustic wave filter of FIG. 1, and FIG. 3 is a graph for depicting a period of the series resonator of FIG. 2.

Referring to FIG. 2, the series resonator 200 can include first and second bus bars 210 and 220, and a plurality of first and second IDT electrodes 230 and 240. The series resonator 200 of FIG. 2 may be any one of the plurality of series resonators (SR) of FIG. 1, and particularly, may be a series resonator, which has the highest resonance frequency or the second highest resonance frequency, among the plurality of series resonators (SR). Therefore, the series resonator having the higher resonance frequency has the structure of FIG. 2, thereby showing improved effects of the right-side attenuation characteristics of the surface acoustic wave filter 1 due to the relevant structure.

The series resonator 200 can have one end 201 and the other end 202. The outermost located IDT electrodes can be respectively positioned at the one end 201 and the other end 202 of the series resonator 200. A first reflector 310 can be positioned to face the one end 201 of the series resonator 200, and a second reflector 320 can be positioned to face the other end 202.

The first and second bus bars 210 and 220 can extend on a substrate, on which the series resonator 200 is formed, to be spaced apart from each other in a second direction (D2) and to be parallel in a first direction (D1). The first and second bus bars 210 and 220 can include conductive material, or can have a structure where a conductive material and an insulating material are layered by turns.

The series resonator 200 can be positioned within a first area (A1), a second area (A2), and a third area (A3) arranged sequentially in the first direction (D1). Accordingly, the first and second bus bars 210 and 220 can traverse the first to third areas (A1 to A3) in the first direction (D1), and the plurality of first and second bus bars 210 and 220 can be arranged to extend within the first to third areas (A1 to A3) in the second direction (D2).

The plurality of first IDT electrodes 230 can extend from the first bus bar 210 toward the second bus bar 220 in the second direction (D2). Additionally, the plurality of second IDT electrodes 240 can extend from the second bus bar 220 toward the first bus bar 210 in the second direction (D2). The plurality of first IDT electrodes 230 and second IDT electrodes 240 can be arranged to traverse the first to third areas (A1 to A3) in the second direction (D2).

The plurality of first IDT electrodes 230 can be spaced apart from the second bus bar 220, and the plurality of second IDT electrodes 240 can be spaced apart from the first bus bar 210. Moreover, the plurality of first IDT electrodes 230 and the plurality of second IDT electrodes 240 can be alternately arranged. That is, one first IDT electrode can extend from the first bus bar 210 toward the second bus bar 220, and one second IDT electrode adjacent to the one first IDT electrode can extend from the second bus bar 220 toward the first bus bar 210.

Therefore, one first IDT electrode can be adjacent to two second IDT electrodes on both sides, and one second IDT electrode can be adjacent to two first IDT electrodes on both sides.

Any one of the plurality of first IDT electrodes 230 can be arranged with a predetermined period relative to one first IDT electrode which is closest in the first direction (D1). The multiple second IDT electrodes 230 can also be arranged with a predetermined period in the first direction (D1). The arrangement period of IDT electrodes of the series resonator 200 included in the surface acoustic wave filter according to the present invention can vary depending on the arrangement locations of the IDT electrodes.

That is, the arrangement period (L1) of the plurality of first IDT electrodes 250 arranged in the second area (A2) can differ from the arrangement periods (L2, L3, L4, L5) of the plurality of first IDT electrodes 230 and 260 arranged in the first area (A1) or the third area (A3).

The plurality of first IDT electrodes 250 arranged in the second area (A2) can be arranged with a constant arrangement period (L1). The arrangement period of the plurality of first IDT electrodes 250 in the second area (A2) can be considered as a reference period (L1).

Meanwhile, the plurality of first IDT electrodes 230 arranged in the first area (A1) may have the arrangement period that is gradually decreased toward one end 201 of the series resonator 200. In addition, the plurality of first IDT electrodes 230 arranged in the third area (A3) may also have the arrangement period that is gradually decreased toward the other end 202 of the series resonator 200.

For example, the three first IDT electrodes arranged in the first area (A1) will be described. The first IDT electrode 232 arranged adjacent to the second area (A2) and the first IDT electrode 231 adjoining in the direction of the one end 201 of the series resonator from the first IDT electrode 232 have the arrangement period (L2), and the other first IDT electrode 230 adjoining to the first IDT electrode 231 in the direction of the one end 201 has the arrangement period (L3). In this instance, the reference period (L1) and the arrangement periods (L2 and L3) have the following relationship:

L1>L2>L3.

That is, the first IDT electrodes arranged in the first area (A1) are arranged with a period which is smaller than the reference period (L1) and gradually decreases in the direction of the one end 201 of the series resonator 201.

The IDT electrodes arranged in the third area (A3) are the same. The three first IDT electrodes 262 arranged in the third area (A3) will be described. The first IDT electrode 262 arranged adjacent to the second area (A2) and the first IDT electrode 261 adjoining in the direction of the other end 202 of the series resonator from the first IDT electrode 262 have the arrangement period (L4), and the other first IDT electrode 260 adjoining to the first IDT electrode 261 in the direction of the other end 202 has the arrangement period (L5). In this instance, the reference period (L1) and the arrangement periods (L4 and L5) have the following relationship:

L1>L4>L5.

That is, the first IDT electrodes arranged in the third area (A3) are arranged with a period which is smaller than the reference period (L1) and gradually decreases in the direction of the other end 202 of the series resonator 201.

Such an arrangement period of the plurality of first IDT electrodes 230 can be depicted as shown in the graph of FIG. 3. In the graph of FIG. 3, the horizontal axis in the graph of FIG. 3 represents the arrangement period of the IDT electrode, and the vertical axis represents the number of IDT electrodes with the relevant arrangement period.

The first IDT electrodes arranged in the second area (A2) are spaced apart each other to have the reference period (L1), and the first IDT electrodes arranged in the first area (A1) or the third area (A3) can be arranged to have a period that is gradually decreased as getting away from the second area (A2), namely, as getting closer to the one end 201 or the other end 202 of the series resonator.

Such an arrangement structure can also be similarly applied to the plurality of second IDT electrodes 240 extending from the second bus bar 220.

The plurality of second IDT electrodes 240 can be arranged with the same arrangement period as the neighboring second IDT electrodes 240. Specifically, the plurality of second IDT electrodes 240 arranged in the first to third areas (A1 to A3) can be arranged with the arrangement period illustrated in FIG. 3. Therefore, the second IDT electrodes arranged in the second area (A2) can be arranged to be spaced apart from each other with a consistent reference period (L1), and the second IDT electrodes arranged in the first area (A1) or the third area (A3) can be arranged to have a period that is gradually decreased as getting away from the second area (A2), namely, as getting closer to the one end 201 or the other end 202 of the series resonator.

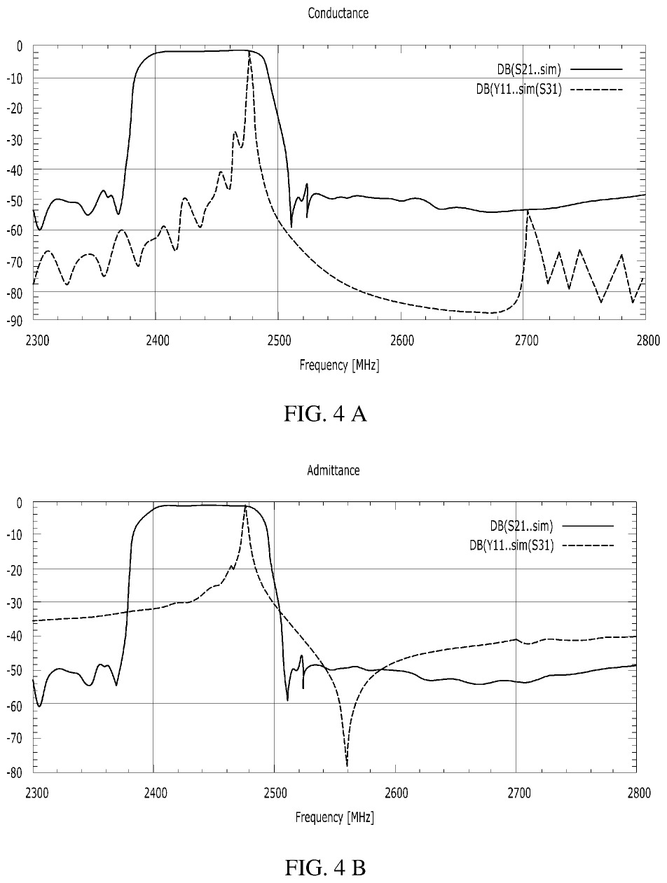

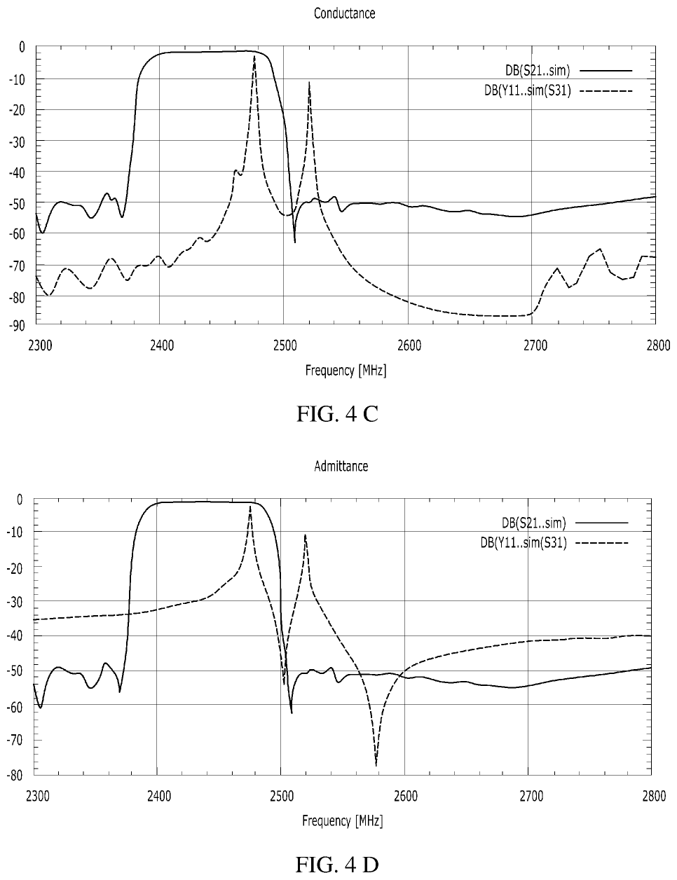

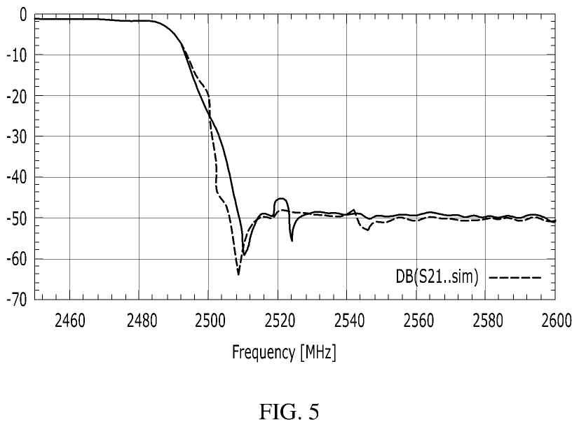

The series resonator included in the surface acoustic wave filter according to an embodiment of the present invention has the arrangement period of the above-mentioned IDT electrodes, thereby causing additional resonance/anti-resonance by the plurality of first and second IDT electrodes arranged in the first area (A1) or the third area (A3). As described above, by the additionally generated resonance/anti-resonance, the attenuation characteristics at the right side of the transmission band can be improved. Referring to the graphs of FIGS. 4 and 5, such effects will be described in detail.

FIG. 4 is a graph for depicting improved attenuation characteristic effect obtainable when the surface acoustic wave filter of the present invention has the structure of the series resonator of FIG. 2, and FIG. 5 is a graph showing an enlargement of a portion of FIG. 4.

Referring to FIG. 4, the two upper graphs show insertion losses of the series resonator when the arrangement period of the IDT electrodes included in the series resonator is constant, in terms of conductance (left upper graph) and admittance (right upper graph). Furthermore, the two lower graphs show insertion losses of the series resonator of FIG. 2 in terms of conductance (left lower graph) and admittance (right lower graph). In the graphs, the red color means a gain (dB) depending on frequencies (MHz), and the blue color means the size of conductance or admittance.

First, in the two upper graphs, through the structure of the existing series resonator, a resonant frequency of about 2475 MHz and an anti-resonant frequency of about 2560 MHz are obtained. As described above, the existing series resonator has one resonant frequency and one anti-resonant frequency.

On the other hand, in the two lower graphs to which the structure of the series resonator 200 of FIG. 2 is applied, two resonant frequencies of about 2475 MHz and 2520 MHz and two anti-resonant frequencies of about 2505 MHz and 2580 MHz are obtained. The resonant frequency of about 2520 MHz and the anti-resonant frequency of about 2505 MHz are located in the right-side skirt area or located adjacent to the right-side skirt area, and are higher than the center frequency of the transmission band.

Referring to FIG. 5, the graph is an enlargement of the frequency band above the transmission band of the graphs of FIG. 4, especially, the frequency band of 2450 MHz to 2600 MHz, to show the relationship between frequencies and insertion losses (dB). The red graph shows insertion losses of the existing series resonator when the arrangement period is constant, and the blue graph shows insertion losses of the series resonator of the embodiment of the present invention.

As illustrated in FIG. 5, it is found that the series resonator of the embodiment of the present invention has attenuation characteristics improved by about 5 dB, and improved sensitivity characteristics.

In summary, the surface acoustic wave filter of the present invention can have improved attenuation and sensitivity characteristics on the right side of the transmission band due to the structure in which the arrangement period of the IDT electrodes becomes smaller as approaching the one end or the other end of the series resonator 200.

Meanwhile, the arrangement period between the plurality of first or second IDT electrodes arranged in the first area (A1) or the third area (A3), and the arrangement period between the plurality of first or second IDT electrodes arranged in the second area (A2) can be within a range of 88% to 97% of the arrangement period between the plurality of first or second IDT electrodes arranged in the second area (A2). In other words, the reference period (L1) and the arrangement periods (L2, L3) or the arrangement periods (L4, L5) can have the following size relationship:

0.97×L1≥L2 or L4>L3 or L5≥0.88×L1.

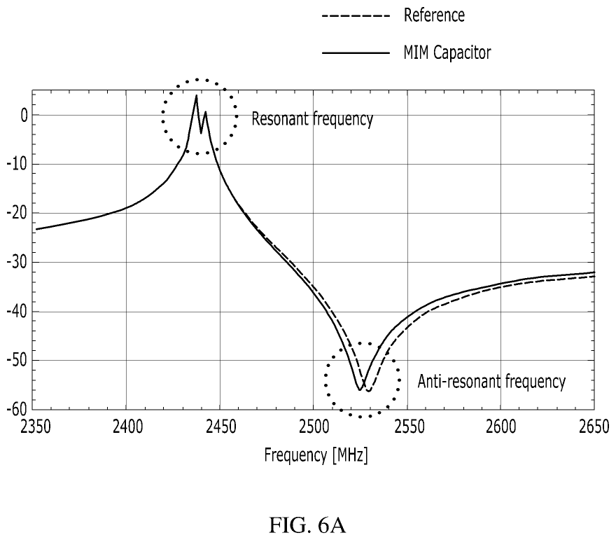

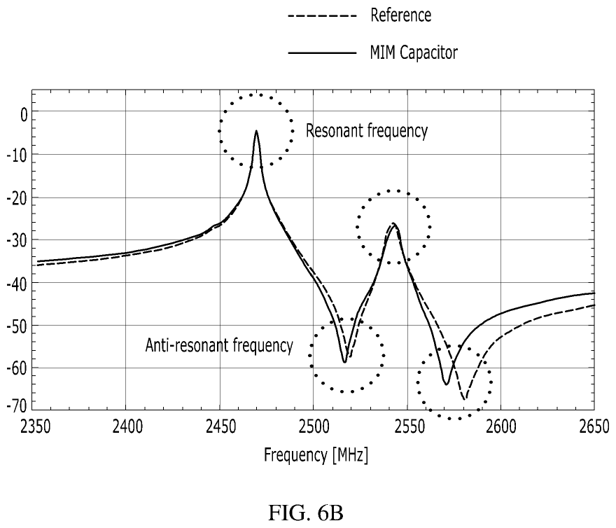

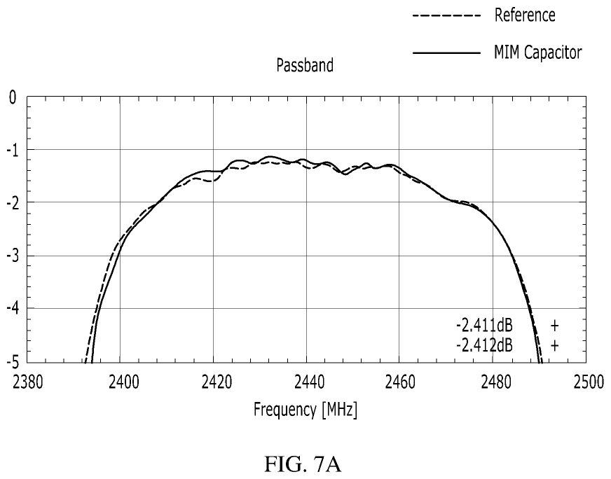

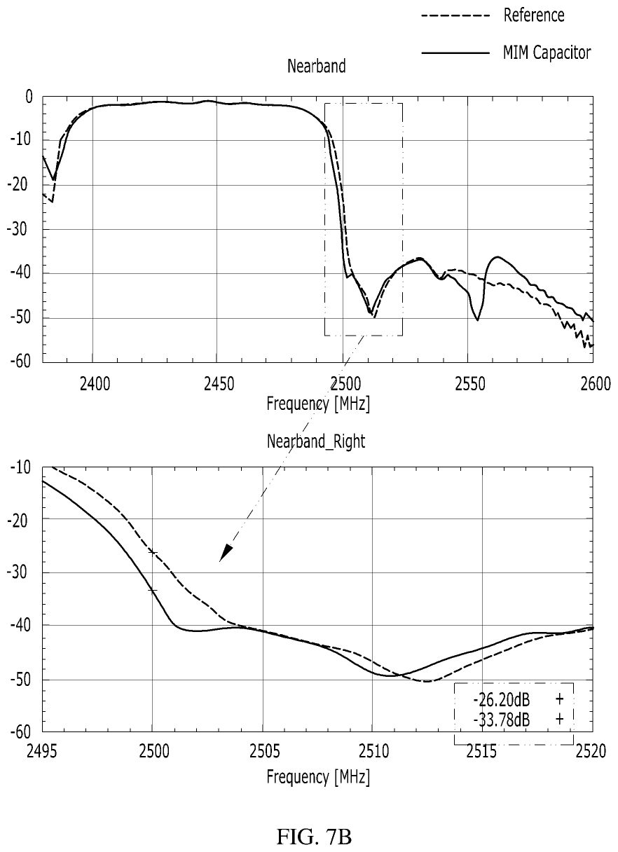

FIGS. 6 and 7 are graphs for depicting improved attenuation characteristic effect obtainable by a capacitor included in the surface acoustic wave filter of the present invention.

Firstly, FIG. 6A is an admittance graph when the series resonator has one resonance frequency and one anti-resonance frequency, which is different from the series resonator of the present invention illustrated in FIG. 2, and FIG. 6B is an admittance graph when the series resonator has two resonance frequencies and two anti-resonance frequencies like the series resonator illustrated in FIG. 2.

In the graphs, the red graph represents the admittance graph of a configuration where the first capacitor (C1) is connected in parallel with the series resonator, and the black graph is the admittance graph of a configuration where the capacitor is not connected in parallel. Due to the connection of the first capacitor (C1), the electromechanical coupling coefficient (K2) of the series resonator connected in parallel decreases. Proportionally, the difference between the resonance frequency and the anti-resonance frequency can also decrease. The two graphs of FIGS. 6A and 6B both show that the anti-resonant frequency shifts downward by about 5 to 10 MHz when the first capacitor (C1) is connected.

In addition, as illustrated in the insertion loss graphs of the passband and the nearband in FIG. 7, in the red graph, the insertion loss of the configuration in which the first capacitor (C1) is connected in parallel with the series resonator has been improved by approximately 7.5 dB around 2500 MHz It shows that the right-side attenuation and desensitivity (De-sense) characteristics have been improved as moving in the direction that the anti-resonant frequencies of the series resonators decrease.

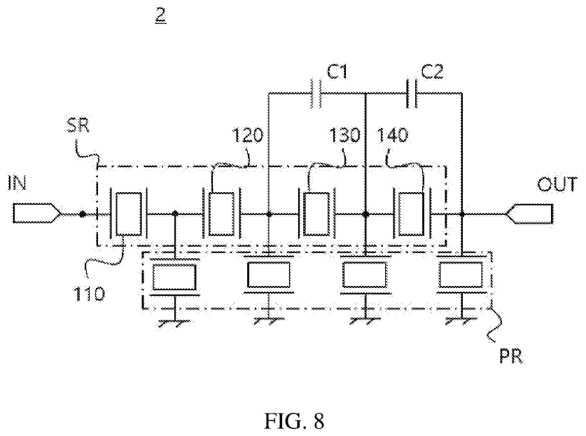

FIG. 8 is a circuit diagram of a surface acoustic wave filter with improved attenuation characteristics according to another embodiment of the present invention.

Referring to FIG. 8, a surface acoustic wave filter 2 according to another embodiment of the present invention may further include a second capacitor (C2) connected in parallel with the series resonator 140.

That is, the surface acoustic wave filter 2 according to another embodiment of the present invention may include two or more series resonators 130 and 140 and two or more capacitors (C1, C2) respectively connected in parallel. In several embodiments of the present invention, the second capacitor (C2) can include an MIM capacitor, and more specifically, the second capacitor (C2) can include an IDT capacitor which is formed by stacking a plurality of IDT electrodes with a dielectric film sandwiched in between. That is, in order to reduce influences, for example, the notch occurrence in the skirt area, when two or more MIM capacitors vertically overlap the first and second capacitors (C1, C2), an IDT capacitor which has larger K² value can be adopted for the second capacitor (C2).

The first capacitor (C1) and the second capacitor (C2) can be connected in parallel with the series resonators that most significantly influence the right-side attenuation characteristics of the surface acoustic wave filter 2, among the plurality of series resonators (SR). Therefore, the first capacitor (C1) can be connected in parallel with the series resonator 130 having the highest resonance frequency among the plurality of series resonators (SR), and the second capacitor (C2) can be connected in parallel with the series resonator 140 having the second-highest resonance frequency. FIG. 8 illustrates that the series resonators 130 and 140 have the highest resonance frequencies and the first and second capacitors (C1, C2) are connected to the series resonators 130 and 140. Similar to the surface acoustic wave filter 1 illustrated in FIG. 1, due to the first and second capacitors (C1, C2), the series resonators move in the direction that the anti-resonant frequencies of the series resonators 130 and 140 connected in parallel with the first and second capacitors (C1, C2) decrease, and the right-side attenuation characteristics of the surface acoustic wave filter 2 can be improved.

The above description is only exemplary, and it will be understood by those skilled in the art that the disclosure may be embodied in other concrete forms without changing the technological scope and essential features. Therefore, the above-described embodiments should be considered only as examples in all aspects and not for purposes of limitation.

What is claimed is:

1. A surface acoustic wave filter comprising:
a plurality of series resonators which are connected between an input terminal and an output terminal; and
at least one parallel resonator which connects between a ground terminal and two adjacent series resonators among the plurality of series resonators,
wherein at least one of the plurality of series resonators includes:
first and second bus bars, which extend parallel to each other in a first direction within first to third areas sequentially arranged on a substrate;
a plurality of first interdigital (IDT) transducer electrodes which extend in a second direction perpendicular to the first direction from the first bus bar; and
a plurality of second IDT electrodes which extend in the second direction from the second bus bar and are alternately arranged with the plurality of first IDT electrodes,
wherein the plurality of first IDT electrodes and the plurality of second IDT electrodes are alternately arranged with a reference period in the second area, are alternately arranged in the first area with a period which gets smaller than a reference period in the direction of one end of the first bus bar, and are alternately arranged in the third area with a period which gets smaller than a reference period in the direction of the other end of the first bus bar.

2. The surface acoustic wave filter according to claim 1, wherein the period at which the plurality of first IDT electrodes and the plurality of second IDT electrodes are arranged in the first and third areas decreases towards the one end or the other end of the first bus bar within a range of 88% to 97% of the reference period.

3. The surface acoustic wave filter according to claim 1, wherein at least one of the plurality of series resonators has two or more resonant frequencies and anti-resonant frequencies.

4. The surface acoustic wave filter according to claim 1, further comprising:
a first capacitor which is connected in parallel with a first series resonator among the plurality of series resonators.

5. The surface acoustic wave filter according to claim 4, wherein the first capacitor has a metal-insulator-metal (MIM) structure.

6. The surface acoustic wave filter according to claim 4, wherein the first series resonator has the highest resonant frequency among the plurality of series resonators.

7. The surface acoustic wave filter according to claim 4, wherein the first capacitor decreases the electromechanical coupling coefficient (K²) of the first series resonator.

8. The surface acoustic wave filter according to claim 4, further comprising:
a second capacitor which is connected in parallel with a second series resonator among the plurality of series resonators.

9. The surface acoustic wave filter according to claim 8, wherein the second series resonator has the second highest resonant frequency among the plurality of series resonators, after the resonance frequency of the first series resonator.

10. The surface acoustic wave filter according to claim 8, wherein the second capacitor has an IDT capacitor structure or an MIM structure.

11. The surface acoustic wave filter according to claim 1, wherein at least one of the plurality of series resonators includes: a first reflector formed on the substrate to face the one end of the first bus bar; and a second reflector formed on the substrate to face the other end of the first bus bar.

12. A surface acoustic wave filter comprising:
a plurality of series resonators which are connected between an input terminal and an output terminal;
a first capacitor which is connected in parallel with a first series resonator among the plurality of series resonators; and
at least one parallel resonator which connects between a ground terminal and two adjacent series resonators among the plurality of series resonators,
wherein at least one of the plurality of series resonators includes:
first and second bus bars, which extend parallel to each other in a first direction within first to third areas sequentially arranged on a substrate;
a plurality of first interdigital (IDT) transducer electrodes which extend in a second direction perpendicular to the first direction from the first bus bar; and
a plurality of second IDT electrodes which extend in the second direction from the second bus bar and are alternately arranged with the plurality of first IDT electrodes,
wherein the plurality of first IDT electrodes and the plurality of second IDT electrodes are alternately arranged with a reference period in the second area, and are alternately arranged in the first area and the third area with a period different from the reference period, and
wherein the first series resonator has the highest resonant frequency among the plurality of series resonators.

13. The surface acoustic wave filter according to claim 12, wherein the plurality of first IDT electrodes and the plurality of second IDT electrodes are alternately arranged in the first area with a period which gets smaller than a reference period in the direction of one end of the first bus bar, and are alternately arranged in the third area with a period which gets smaller than a reference period in the direction of the other end of the first bus bar.

14. The surface acoustic wave filter according to claim 13, wherein the period at which the plurality of first IDT electrodes and the plurality of second IDT electrodes are arranged in the first and third areas decreases towards the one end or the other end of the first bus bar within a range of 88% to 97% of the reference period.

15. The surface acoustic wave filter according to claim 12, wherein the first capacitor has a metal-insulator-metal (MIM) structure.

16. The surface acoustic wave filter according to claim 12, wherein the first capacitor decreases the electromechanical coupling coefficient (K2).

17. The surface acoustic wave filter according to claim 12, further comprising:
a second capacitor which is connected in parallel with a second series resonator among the plurality of series resonators.

18. The surface acoustic wave filter according to claim 17, wherein the second series resonator has the second highest resonant frequency among the plurality of series resonators, after the resonance frequency of the first series resonator.

19. The surface acoustic wave filter according to claim 17, wherein the second capacitor has an IDT capacitor structure or an MIM structure.

20. The surface acoustic wave filter according to claim 12, wherein at least one of the plurality of series resonators has two or more resonant frequencies and anti-resonant frequencies.
